(19) United States
(12) Patent Application Publication
(10) Pub. No.: US 2026/0121656 A1
(43) Pub. Date: Apr. 30, 2026

(54) CURRENT-TO-TIME CONVERTER FOR TIME-MODE DIRECT SENSING

(71) Applicant: KING FAHD UNIVERSITY OF PETROLEUM AND MINERALS, Dhahran (SA)

(72) Inventor: Muneer A. AL-ABSI, Dhahran (SA)

(73) Assignee: KING FAHD UNIVERSITY OF PETROLEUM AND MINERALS, Dhahran (SA)

(21) Appl. No.: 18/929,762

(22) Filed: Oct. 29, 2024

(30) Foreign Application Priority Data
Oct. 24, 2024 (SA) 1020245979

(51) Int. Cl. H03M 1/50; G05F 3/26

(52) U.S. Cl. CPC H03M 1/502; G05F 3/262

(57) ABSTRACT

A linear CMOS current-to-time converter including an inverse circuit that generates an output voltage having a time delay directly proportional to an input current. The output current is supplied to a mirror transistor, where the drain and gate terminals are connected to the inverse circuit, and the source terminal is connected to the ground rail. A voltage-to-time converter (VTC) is implemented between the positive rail and the ground rail. The VTC comprises a series connection of three transistors with the gate terminal of the third transistor connected to the mirror transistor. A clock generator interfaces with the gate terminals of the first two transistors and a digital inverter produces an output voltage. The time delay of the output voltage is linearly proportional to the input current.

### CROSS REFERENCE TO RELATED APPLICATIONS

The present application claims the benefit of priority to Saudi Patent Application No. 1020245979, filed on Oct. 24, 2024, with the Saudi Authority for Intellectual Property Office, which is incorporated herein by reference in its entirety.

### STATEMENT OF ACKNOWLEDGEMENT

Financial support provided by the King Fahd University of Petroleum and Minerals (KFUPM), Dhahran, Saudi Arabia and the Interdisciplinary Research Center for Smart Mobility and Logistics through Grant No. INML2108 is gratefully acknowledged.

### BACKGROUND

### Technical Field

The present disclosure is directed to a linear complementary metal-oxide-semiconductor (CMOS) current-to-time converter for time-mode direct sensing.

### Description of Related Art

The “background” description provided herein is for the purpose of generally presenting the context of the disclosure. Work of the presently named inventors, to the extent it is described in this background section, as well as aspects of the description which may not otherwise qualify as prior art at the time of filing, are neither expressly or impliedly admitted as prior art against the present invention.

An analog-to-digital converter (ADC) is an integral component of various electronic systems that are implemented to convert analog signals into digital data. The continuous scaling of technology presents various challenges, such as achieving high-speed and low-power operation. To overcome the challenges, a new class of time-based ADCs was developed. Time-based ADCs are advantageous in terms of reduced power consumption, smaller footprint, and the capability to operate at high clock and input frequencies. Additionally, time-to-digital converters (TDCs) are also being developed due to their capability to overcome the inherent limitations of conventional ADCs.

Time-based ADCs consist of two stages, including a voltage-to-time converter (VTC) and a time-to-digital converter (TDC). The VTC serves as the initial stage, in which the input analog signal is converted into delay pulses. The delay of each pulse is directly related to the value of the input voltage signal. To effectively handle sensor outputs, the VTC requires a large input range. In the subsequent stage, the TDC converts the delay pulses into a digital code.

The performance of time-based ADCs is dependent on the VTC. However, VTCs are often susceptible to nonlinearity and process variation (PVT) effects, which can degrade overall performance. Various configurations of VTCs have been developed conventionally to address these challenges. In an example, some configurations utilize current-starved inverters to linearize inverter delays through parallel current-starved devices with different gate bias voltages. However, such designs may have a limited input signal range, for example, as low as 0.0 to 0.3 volts. Other configurations, such as those employing pulse width modulation (PWM), include applying an input analog signal to two current-starved inverters, with the output processed through an XNOR gate.

Further, VTC configurations based on pipelines and configurations incorporating multiple stages and complex switching mechanisms have also been implemented. Despite each configuration having advantages, the increased complexity and requirement of a significant number of components, such as constant current sources, capacitors, comparators, and resistors, remains a challenge. Furthermore, some configurations utilize differential-based VTCs, including inductors and various such elements for DC coupling. Despite the advancements, challenges such as nonlinearity, limited voltage input range, and increased design complexity remain prevalent. In other configurations, the sensor output is in the form of a current signal, necessitating the use of a current-to-voltage converter for direct sensing

US20140284459A1 describes a light receiving circuit that includes a current input (Iₚ₁), a mirror circuit (M₇ and M₈), and a VTC circuit at the output (M₅ and M₈). However, the described configuration is based on a current-to-voltage converter, resulting in a time delay that is inversely proportional to the voltage and the current. The light-receiving circuit introduces nonlinearity errors and relies on many passive elements, which increases a required silicon area.

Each of the aforementioned references presents developments in configurations of VTCs and CTCs, however, the existing configurations possess limitations in their scope and capability. However, these references fail to address aspects, such as achieving high linearity across a wide input range, minimizing silicon area, and reducing design complexity, which are essential for the efficient performance of time-based ADCs in various applications.

Thus there exists a need for a compact, linear CMOS current-to-time converter that can be effectively utilized in direct sensing applications. There is also a need for a method to enhance the linearity and input range of VTCs while minimizing the silicon area and complexity of the configuration. Accordingly, it is one of the objectives of the present disclosure to provide a system and method for a linear CMOS current-to-time converter which is efficient, scalable, and provides high-performance time-based current to time delay conversion.

### SUMMARY

In an exemplary embodiment, a linear CMOS current-to-time converter is described. The linear CMOS current-to-time converter comprises a printed circuit board having a positive rail connected to a DC voltage source (V_{DD}) and a ground rail connected to a ground and an inverse circuit connected between the positive rail and the ground rail. The inverse circuit is configured to generate an output current Iₒ. The linear CMOS current-to-time converter further comprises a mirror transistor M₁₄ connected to the inverse circuit. A drain terminal and a gate terminal of the mirror transistor M₁₄ are connected to receive the output current Iₒ and a source terminal of the mirror transistor M₁₄ is connected to the ground rail. The linear CMOS current-to-time converter further comprises a voltage-to-time converter (VTC) connected between the positive rail of the V_{DD} and the ground rail. The VTC includes a series connection of a first transistor M₁, a second transistor M₂, and a third transistor M₃. A gate terminal of the third transistor M₃ is connected to a gate terminal of the mirror transistor M₁₄ and a source terminal of the third transistor M₃ is connected to the ground rail. The linear CMOS current-to-time converter further comprises a clock generator connected to a gate terminal of the first transistor M₁ and to a gate terminal of the second transistor M₂, and a digital inverter connected between a drain terminal of the first transistor M₁ and a drain terminal of the second transistor M₂. The digital inverter is configured to generate an output voltage Vₒ. A time delay de of the output voltage Vₒ is linearly proportional to an input current Iᵢₙ.

In another exemplary embodiment, a method for generating an output voltage Vₒ which is linearly proportional to an input current Iᵢₙ using a linear CMOS current to time converter is described. The method comprises connecting an inverse circuit between a positive rail and a ground rail of a printed circuit board having the positive rail connected to a DC voltage source (V_{DD}) and the ground rail connected to a ground terminal, connecting an input current Iᵢₙ source to the inverse circuit, connecting a first fixed current source Ix to the inverse circuit, connecting a second fixed current source I_{y} to the inverse circuit, generating, by the inverse circuit, an output current Iₒ, where Iₒ is given by Iₒ=(Iₓ×I_{y})/Iᵢₙ. The method further comprises connecting a drain terminal and a gate terminal of a mirror transistor M₁₄ to the inverse circuit, receiving, at the drain terminal of mirror transistor M₁₄, the output current Iₒ, and connecting a voltage to time converter (VTC) between the positive rail of the V_{DD} and the ground rail. The VTC includes a series connection of a first transistor M₁, a second transistor M₂, and a third transistor M₃, The method further comprises connecting a gate terminal of the third transistor M₃ to the gate terminal of the mirror transistor M₁₄, and a source terminal of the third transistor M₃ to the ground rail, applying, by a clock generator connected to a gate terminal of the first transistor M₁ and a gate terminal of the second transistor M₂, a time varying clock signal, and generating, by a digital inverter connected between a drain terminal of the first transistor M₁ and a drain terminal of the second transistor M₂, the output voltage Vₒ having a time delay dt which is linearly proportional to the input current Iᵢₙ.

In another exemplary embodiment, a method of converting an input current Iᵢₙ to an output voltage Vₒ having a time delay de proportional to the input current Iᵢₙ is described. The method comprises connecting an inverse circuit of a linear CMOS current to a time converter having a first plurality of CMOS transistors to a positive voltage rail connected to a DC voltage source (V_{DD}), connecting a ground rail of the inverse circuit to a ground terminal, and connecting a drain terminal and a gate terminal of a mirror transistor M₁₄ to the inverse circuit. The method further includes connecting a drain terminal and a gate terminal of a mirror transistor M₁₄ to the inverse circuit and connecting a voltage-to-time converter (VTC) between the positive rail of the V_{DD} and the ground rail. The VTC includes a series connection of a second plurality of CMOS transistors comprising the first transistor M₁, a second transistor M₂, and a third transistor M₃. The first transistor M₁ is a PMOS transistor and the second transistor M₂ and the third transistor M₃ are NMOS transistors. The method further comprises connecting a gate terminal of the third transistor M₃ to the gate terminal of the mirror transistor M₁₄ and connecting a source terminal of the third transistor M₃ to the ground rail, connecting a digital inverter between a drain terminal of the first transistor M₁ and a drain terminal of the second transistor M₂, and configuring a voltage at the gate of the third transistor M₃ to be greater than a threshold voltage of the third transistor M₃ by selecting an aspect ratio W₃/L₃ of the third transistor M₃ and the aspect ratio W₁₄/L₁₄ of the mirror transistor M₁₄ so that a scaling factor k is given by:

$$k = {W}_{3} \times {L}_{14} / {W}_{14} \times {L}_{3} .$$

W₃ represents a channel width of the third transistor M₃, L₁₄ represents a channel length of the mirror transistor M₁₄, W₁₄ represents a channel width of the mirror transistor M₁₄, and L₃ represents a channel length of the third transistor M₃.

The method further comprises connecting a capacitor CL between an input terminal of the digital inverter and the ground rail, applying the input current Iᵢₙ, a first fixed current Iₓ, a second fixed current I_{y} and a bias voltage VB to the inverse circuit and generating an output current I₀, receiving, at the drain of the mirror transistor, the output current I₀, applying, by a clock generator connected to a gate terminal of the first transistor M₁ and a gate terminal of the second transistor M₂, a time-varying clock signal, charging the capacitor C_{L} through the first transistor M₁ when the first transistor M₁ is ON and the third transistor M₃ is OFF, discharging the capacitor C_{L} through the third transistor M₃ when the first transistor M₁ is OFF and second transistor M₂ and the third transistor M₃ are ON, generating, by the inverting output amplifier, the output voltage Vₒ, having a time delay de which is linearly proportional to the input current Iᵢₙ, wherein the time delay di is given by:

$${d}_{t} = ( {C}_{L} \times {V}_{D D} / 2 k ) \times ( {I}_{i n} / ( {I}_{x} \times {I}_{y} ) .$$

The foregoing general description of the illustrative embodiments and the following detailed description thereof are merely exemplary aspects of the teachings of this disclosure and are not restrictive.

### BRIEF DESCRIPTION OF THE DRAWINGS

A more complete appreciation of this disclosure and many of the attendant advantages thereof will be readily obtained as the same becomes better understood by reference to the following detailed description when considered in connection with the accompanying drawings, wherein:

FIG. 1 is a schematic diagram of a time-based analog-to-digital converter (ADC) circuit.

FIG. 2 illustrates an ultra-low power voltage-to-time converter (VTC) circuit, according to certain embodiments.

FIG. 3 illustrates a circuit diagram of a linear complementary metal-oxide-semiconductor (CMOS) current-to-time converter, according to certain embodiments.

FIG. 4 is a graphical representation of a transient response of the linear CMOS current-to-time converter, according to certain embodiments.

FIG. 5 is a graph representing a delay de as a function of the input current Iᵢₙ, according to certain embodiments.

FIG. 6 is a graph representing a temperature analysis conducted with a fixed input current Iᵢₙ, according to certain embodiments.

FIG. 7 is an illustration of a non-limiting example of details of computing hardware used in the computing system, according to certain embodiments.

FIG. 8 is an exemplary schematic diagram of a data processing system used within the computing system, according to certain embodiments.

FIG. 9 is an exemplary schematic diagram of a processor used with the computing system, according to certain embodiments.

FIG. 10 is an illustration of a non-limiting example of distributed components which may share processing with the controller, according to certain embodiments.

### DETAILED DESCRIPTION

In the drawings, like reference numerals designate identical or corresponding parts throughout the several views. Further, as used herein, the words “a”, “an” and the like generally carry a meaning of “one or more”, unless stated otherwise.

Furthermore, the terms “approximately,” “approximate”, “about” and similar terms generally refer to ranges that include the identified value within a margin of 20%, 10%, or preferably 5%, and any values therebetween.

Aspects of this disclosure relate to a linear complementary metal-oxide-semiconductor (CMOS) current-to-time converter configured to convert an input current signal into a corresponding time delay signal. The linear CMOS current-to-time converter includes an inverse circuit connected to a current-to-voltage converter, which generates a delay dt which is proportional to the input current signal. The linear CMOS current-to-time converter, fabricated using 0.18 μm CMOS technology, operates with a DC supply voltage of 1.8 V. Simulation was performed to validate the functionality and effectiveness of the linear CMOS current-to-time converter, confirming that the linear CMOS current-to-time converter performs the current-to-time conversion as intended.

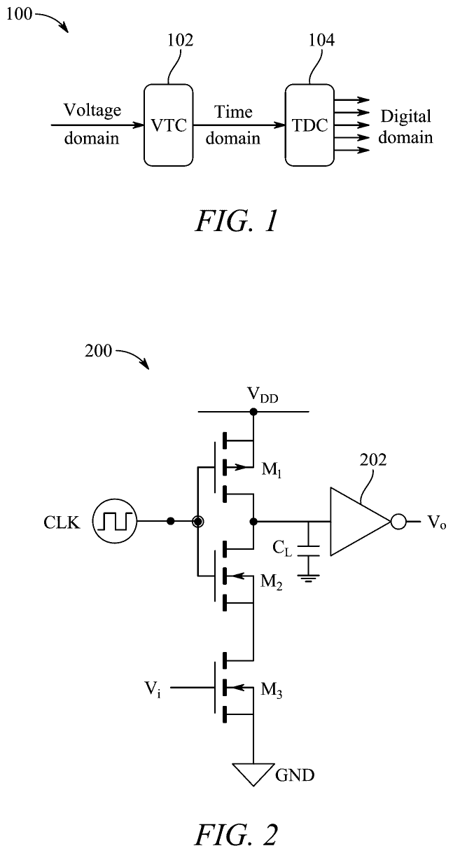

FIG. 1 is a schematic diagram of a time-based ADC (TDC) circuit 100 configured to transform an input analog signal into a digital code. The TDC circuit 100 is implemented in applications requiring high-speed, low-power signal conversion. The TDC circuit 100 includes a voltage-to-time converter (VTC) 102 and a TDC 104.

In a voltage domain, an input voltage Vᵢₙ is applied to the VTC 102. In the voltage domain, the input voltage signal Vᵢₙ is processed. The VTC 102 is configured for converting the input voltage Vᵢₙ into a corresponding time delay t_{d} in time interval pulses and is directly influenced by the magnitude of the input voltage Vᵢₙ.

In the time domain, the time interval t_{d} generated by the VTC 102 is processed. The time interval t_{d} is linearly proportional to the input current Iᵢₙ. The time interval t_{d} is used as the input to the TDC 104 within a digital domain.

In the digital domain, the time interval t_{d} is converted into a corresponding digital code Dₒ by the TDC 104. In the digital domain, the time-based signal is transformed into a digital format for processing in digital circuits.

FIG. 2 illustrates an ultra-low power Voltage-to-Time Converter (VTC) circuit 200. As described in FIG. 1, the TDC circuit 100 is configured in two stages including the VTC to convert the input voltage Vᵢₙ into delay pulses in the voltage domain and the TDC to introduce the controlled delay into the delay pulses in the time domain. The ultra-low power VTC circuit 200 is based upon the TDC circuit 100 and configured in the stages, converting voltage input Vᵢₙ into the delay pulses and introducing the controlled delay to the delay pulses.

The ultra-low power VTC circuit 200 is configured to regulate the discharging current of a capacitor C_{L} to control the delay in a falling edge of the clock signal, thereby converting an input voltage Vᵢ into a corresponding time delay dₜ within the time-to-digital conversion process.

The ultra-low power VTC circuit 200 includes a series connection of three transistors. The three transistors include a first transistor M₁, a second transistor M₂, and a third transistor M₃. The first transistor M₁ is a P-type Metal-Oxide-Semiconductor (PMOS) transistor, while the second transistor M₂ and the third transistor M₃ are N-type Metal-Oxide-Semiconductor (NMOS) transistors. The selection of PMOS and NMOS transistors are defined for controlling current flow and, consequently, timing characteristics of the circuit.

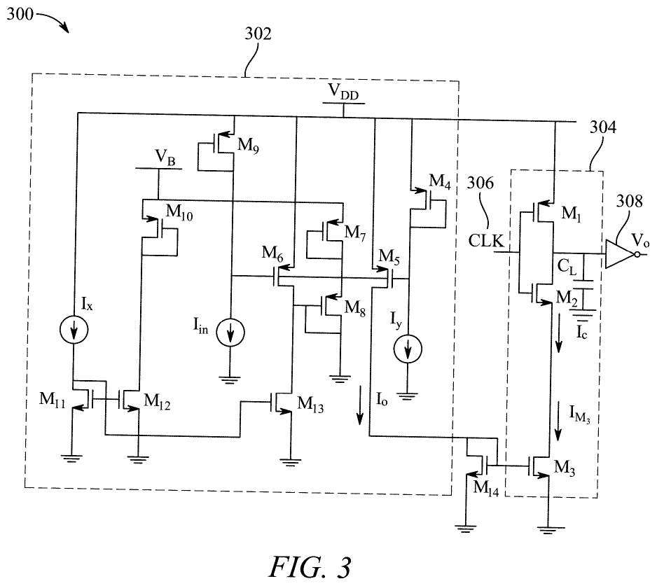

A gate terminal of the first transistor M₁ is connected to a clock generator (CLK) implemented to control the switching cycle of M₁. A source terminal of the first transistor M₁ is connected to a positive rail of the DC voltage source V_{DD}. A drain terminal of the first transistor M₁ is connected to a drain terminal of the second transistor M₂. The second transistor M₂ is connected in series with the third transistor M₃, with a source terminal of M₂ connected to a drain terminal of M₃, and a source terminal of M₃ connected to a ground rail GND. The gate terminal of the second transistor M₂ and a gate terminal of the third transistor M₃ are connected to the clock generator CLK and the output of a mirror transistor M₁₄ (shown in FIG. 3), respectively.

The ultra-low power VTC circuit 200 includes a digital inverter 202. The digital inverter 202 is configured to invert and amplify an output voltage Vₒ of the VTC circuit 200. The capacitor C_{L} is connected between an input terminal of the digital inverter 202 and the ground rail GND.

In the operation of the ultra-low power VTC circuit 200, when the first transistor M₁ is ON and the third transistor M₃ is OFF, the capacitor C_{L} charges. When the first transistor M₁ is OFF, and the second transistor M₂ and the third transistor M₃ are ON, the capacitor C_{L} discharges through the third transistor M₃. The discharging current i_{c} received at the drain terminal of the third transistor M₃ determines the time delay dₜ of the output voltage Vₒ, which is generated by the digital inverter 202.

The delay dₜ is mathematically expressed as:

$${d}_{t} = ( {c}_{L} {d}_{V C} ) / {i}_{C} = ( {C}_{L} {d}_{V C} ) / {I}_{M 3} , \qquad ( 1 )$$

where i_{c} is the capacitor discharging current, C_{L} is the total capacitance at the drain of transistor M₂ and dₜ is the delay in seconds. The input voltage Vᵢ controls the current in M₃, which is equal to the current in the capacitor C_{L}. In this configuration, an aspect ratio is selected. The aspect ratio refers to the ratio of a width (W) of the transistor to a length (L) of the transistor. By selecting an aspect ratio, the third transistor M₂ is compelled to operate in saturation, and as a result, the drain current is determined by:

$${I}_{M 3} = {k ( {V}_{GS 3} - {V}_{T o} )}^{2} / ( {V}_{GS 3} - {V}_{T o} ) + L {E}_{C} , \qquad ( 2 )$$

where k is a scaling factor given by k=(μₙCₒₓ/2)×(W₃/L₃), where μₙ is a charge carrier effective mobility of the third transistor M₃, Cₒₓ is a gate oxide capacitance per unit area of the third transistor M₃, W₃ is a width of the third transistor M₃ and L₃ is a length of the third transistor M₃.

LE_{c} of equation (2) is insignificant for short channel transistors, and equation (2) is roughly represented by:

$${I}_{M 3} = k ( {V}_{G 3} - {V}_{{T}_{0}} ) , \qquad ( 3 )$$

where V_{T}_{₀} is the threshold voltage at the gate of transistor M₃.

From equations (1) and (3), and calculating the delay de the switching point, the delay is given by:

$${d}_{t} = ( {c}_{L} {d}_{V C} ) / ( {k ( {V}_{{i}^{-}} {V}_{{T}_{0}} )}^{2} = ( {c}_{L} {V}_{D D} / 2 ) / {i}_{c} \qquad ( 4 )$$

The delay dₜ is inversely proportional to the square of the input voltage Vᵢ, resulting in a nonlinear relationship between the delay de and the input voltage Vᵢ. The nonlinearity is a significant limitation of the ultra-low power VTC circuit 200, as the nonlinearity affects the accuracy and reliability of the time delay generated for varying input signals.

FIG. 3 illustrates a circuit diagram of the linear CMOS current-to-time converter 300 of the present disclosure. The linear CMOS current-to-time converter is configured to generate a time delay de that is linearly proportional to an input current, providing a solution to the nonlinearity issues inherent in the voltage to time converter shown in FIG. 2.

The linear CMOS current-to-time converter 300 includes a printed circuit board (PCB) having a positive rail connected to a DC voltage source (V_{DD}) and a ground rail connected to a ground terminal. The PCB provides a physical structure for mounting and interconnecting all the components of the converter circuit. The PCB serves as the platform upon which the various electronic components, such as transistors, resistors, capacitors, and other integrated circuits, are mounted and electrically connected.

The linear CMOS current-to-time converter 300 includes an inverse circuit 302, which is connected between the positive rail of the DC voltage source V_{DD} and the ground rail. The inverse circuit 302 is configured to generate an output current Iₒ that is used in the subsequent stages of the linear CMOS current-to-time converter 300. The inverse circuit 302 includes a plurality of transistors consisting of a fourth transistor M₄, a fifth transistor M₅, a sixth transistor M₆, a seventh transistor M₇, an eighth transistor M₈, a ninth transistor M₉, a tenth transistor M₁₀, an eleventh transistor M₁₁, a twelfth transistor M₁₂, and a thirteenth transistor M₁₃. Each of the plurality of transistors (M₄-M₁₃) has a gate terminal, a drain terminal, and an input terminal. The configuration of the plurality of transistors within the inverse circuit 302 generates the output current Iₒ, which is inversely proportional to the input current Iᵢₙ.

In the linear CMOS current-to-time converter 300, the first transistor M₁, the fourth transistor M₄, the fifth transistor M₅, the sixth transistor M₆, the seventh transistor M₇, the eighth transistor M₈, the ninth transistor M₉, and the tenth transistor M₁₀ are PMOS transistors. The second transistor M₂, the third transistor M₃, the eleventh transistor M₁₁, the twelfth transistor M₁₂, the thirteenth transistor M₁₃, and the mirror transistor M₁₄ are NMOS transistors. The selection of the PMOS transistors and the NMOS transistors are characterized by the operation of the linear CMOS current-to-time converter 300 across different stages, providing controlled switching and current mirroring functions.

An electrical connector is implemented between the drain terminal of the eleventh transistor M₁₁ and the gate terminal of the thirteenth transistor M₁₃, with both the source terminal of the eleventh transistor M₁₁ and the source terminal of the thirteenth transistor M₁₃ being connected to the ground rail. Additionally, an electrical connector is implemented between the gate terminal of the eleventh transistor M₁₁, and the gate terminal of the twelfth transistor M₁₂. The source terminal of the twelfth transistor M₁₂ is also connected to the ground rail. A DC bias voltage source V_{B} is connected to the source terminal of the tenth transistor M₁₀ via an electrical connector, with the drain terminal of the tenth transistor M₁₀ being connected to the drain terminal of the twelfth transistor M₁₂. The gate terminal of the tenth transistor M₁₀ is also connected to its own drain terminal. Furthermore, an electrical connector is provided between the positive rail of the V_{DD} and the source terminal of the ninth transistor M₉, establishing a connection between the gate terminal of the ninth transistor M₉ and the drain terminal of the ninth transistor M₉. The DC bias voltage source V_{B} is about 0.9 V.

The positive rail of the V_{DD} is further connected to the source terminal of the sixth transistor M₆. A connection is implemented between the gate terminal of the sixth transistor M₆ and the drain terminal of the ninth transistor M₉. The drain terminal of the sixth transistor M₆ is connected to the drain terminal of the thirteenth transistor M₁₃.

An electrical connector is implemented between the source terminal of the seventh transistor M₇ and the source terminal of the tenth transistor M₁₀, with a connection implemented between the gate terminal of the seventh transistor M₇ and the drain terminal of the seventh transistor M₇. The drain terminal of the seventh transistor M₇ is further connected to the source terminal of the eighth transistor M₈. Additionally, an electrical connection is provided between the gate terminal of the eighth transistor M₈, and the drain terminal of the sixth transistor M₆. The gate terminal of the eighth transistor M₈ is also connected to its own drain terminal, with the drain terminal of the eighth transistor M₈ being connected to the ground rail.

The positive rail of the V_{DD} is connected to the source terminal of the fifth transistor M₅, with the body terminal of the fifth transistor M₅ being connected to the body terminal of the sixth transistor M₆. Additionally, an electrical connector is provided between the drain terminal of the fifth transistor M₅ and the drain terminal of the mirror transistor M₁₄. The connection is configured to supply the output current I₀ to the drain terminal of the mirror transistor M₁₄.

The positive rail of the V_{DD} is connected to the source terminal of the fourth transistor M₄, with an electrical connector between the gate terminal of the fourth transistor M₄ and its drain terminal. Additionally, a connection is established between the drain terminal of the fourth transistor M₄ and the gate terminal of the fifth transistor M₅, and between the drain terminal of the fourth transistor M₄ and the second fixed current source I_{y}.

The inverse circuit 302 operates by utilizing the fixed current sources Iₓ and I_{y}, connected within the inverse circuit 302. The relationship between the currents Iₓ and I_{y} and the input current Iᵢₙ is given by the equation:

$${I}_{0} = ( {I}_{x} \times {I}_{y} ) / {I}_{i n} = Z / {I}_{i n} , \qquad ( 5 )$$

where Iₓ and I_{y} are fixed to 20 nA and Z=Iₓ×I_{y} [See: Al-Absi, M. A.: Low voltage and low power current-mode divider and 1/x circuit using MOS transistor in subthreshold. Arab J Sci Eng 38., 2411-2414 (2013)]. Equation (5) provides that the output current Iₒ is a function of the input current Iᵢₙ, which in turn controls the time delay de generated by the linear CMOS current-to-time converter 300.

In the configuration of the linear CMOS current-to-time converter 300, a mirror transistor M₁₄ is connected to the inverse circuit 302. The mirror transistor M₁₄ is configured for mirroring and scaling the output current Iₒ. The output current Iₒ from the inverse circuit 302 is supplied to the mirror transistor M₁₄. A drain terminal and a gate terminal of the mirror transistor M₁₄ are connected to receive the output current Iₒ, while a source terminal of the mirror transistor M₁₄ is connected to the ground rail. The mirror formed by the mirror transistor M₁₄ and the third transistor M₃ operates such that the current I_{M3} through the third transistor M₃ is a scaled factor of the current I_{M14}, which corresponds to the output current Iₒ.

The mirror formed using M₁₄ and M₃ will force the current I_{M3} to be a scaled factor of I_{M14} which is the same as Iₒ.

$${I}_{M 3} = k {I}_{M 14} = {I}_{o} = k Z / {I}_{i n} , thus {I}_{c} = kZ / {I}_{i n} , \qquad ( 6 )$$

where k is the scaled factor of the mirror and is given by the aspect ratios of I_{M3}/I_{M14}.

In the configuration of the linear CMOS current-to-time converter 300, a VTC 304 is connected between the positive rail of the V_{DD} and the ground rail. The VTC 304 includes a series connection of a first transistor M₁, a second transistor M₂, and a third transistor M₃. The VTC 304 is similar to the ultra-low power VTC circuit 200, as described with reference to FIG. 2. A source terminal of the first transistor M₁ is connected to the positive rail of the V_{DD}, and a drain terminal of the first transistor M₁ is connected to a drain terminal of the second transistor M₂. A source terminal of the second transistor M₂ is connected to a drain terminal of the third transistor M₃, while a source terminal of the third transistor M₃ is connected to the ground rail. A gate terminal of the third transistor M₃ is connected to a gate terminal of the mirror transistor M₁₄.

The linear CMOS current-to-time converter 300 includes a clock generator 306. The clock generator 306 is connected to the gate terminal of the first transistor M₁ and the gate terminal of the second transistor M₂. The clock generator 306 controls the switching of the transistors M₁ and M₂, determining the timing of the voltage-to-time conversion. When the clock signal is high, the first transistor M₁ turns ON, and the capacitor C_{L} is charged. Conversely, when the clock signal goes low, the first transistor M₁ turns OFF, and the second transistor M₂ and third transistor M₃ turn ON, causing the capacitor C_{L} to discharge through the third transistor M₃.

A digital inverter 308 is connected between the drain terminal of the first transistor M₁ and the drain terminal of the second transistor M₂. The digital inverter 308 is configured to generate an output voltage Vₒ, with a time delay dₜ that is linearly proportional to the input current Iᵢₙ.

The time delay dₜ is determined by combining equations (4) and (6), as:

$${d}_{t} = {I}_{i n} ( {C}_{L} {V}_{D D} / 2 ) / kZ \qquad ( 7 )$$

As defined in equation (5), Z=Iₓ×I_{y}, equation (7) can be rewritten as:

$${d}_{t} = ( {C}_{L} \times {V}_{D D} / 2 k ) \times ( {I}_{i n} / ( {I}_{x} \times {I}_{y} ) .$$

Therefore, the time delay dₜ is proportional to the input current Iᵢₙ.

The capacitor C_{L} is connected between the input terminal of the digital inverter 308 and the ground. The capacitor C_{L} charges when the first transistor M₁ is ON and the third transistor M₃ is OFF and discharges through the third transistor M₃ when the first transistor M₁ is OFF and the second transistor M₂ and the third transistor M₃ are ON. The discharge current I_{c} received at the drain terminal of the third transistor M₃ is given by:

$${I}_{c} = k ( {I}_{x} \times {I}_{y} ) / {I}_{i n} = k \times {I}_{0} \qquad ( 8 )$$

where k is a scaling factor given by an aspect ratio of the third transistor M₃ divided by an aspect ratio of the mirror transistor M₁₄. The aspect ratio of the mirror transistor M₁₄ is configured to generate a voltage at the gate of the third transistor M₃ which is greater than a threshold voltage of the third transistor M₃. The threshold voltage is represented as V_{T}_{₀} in equation (3) and equation (4). In an example, the aspect ratio of M3 is about 2/0.18 and the aspect ratio of M14 is about 20/1. Equation (8) demonstrates that the time delay dₜ is directly proportional to the input current Iᵢₙ, providing a linear relationship that improves the accuracy and predictability of the time conversion process over conventional VTC circuits.

The aspect ratio of a MOSFET, defined as the ratio of the channel width (W) to the channel length (L), is a parameter in MOSFET design, typically expressed as W/L. The aspect ratio significantly influences the electrical characteristics of a circuit, including its current conduction capability, switching speed, and power dissipation properties.

The scaling factor k is given by:

$$k = {W}_{3} \times {L}_{14} / {W}_{14} \times {L}_{3} ,$$

where W₃ represents a channel width of the third transistor M₃, L₁₄ represents a channel length of the mirror transistor M₁₄, W₁₄ represents a channel width of the mirror transistor M₁₄, and L₃ represents a channel length of the third transistor M₃.

The linear CMOS current-to-time converter 300 further includes various connections for current flow and signal processing. In one aspect, a source of the input current Iᵢₙ is connected between a drain terminal of the ninth transistor M₉ and the ground rail, with a source terminal of the ninth transistor M₉ connected to the positive rail of the V_{DD} and a gate terminal of the ninth transistor M₉ connected to the drain terminal of the ninth transistor M₉. In the configuration of the linear CMOS current-to-time converter 300, a first fixed current source Iₓ is connected between the positive rail of the V_{DD} and the drain terminal of the eleventh transistor M₁₁. Further, a second fixed current source I_{y} is connected between the drain terminal of the fourth transistor M₄ and the ground rail. The output current Iₒ is given by:

$${I}_{o} = ( {I}_{x} \times {I}_{y} ) / {I}_{i n} .$$

The circuit also includes a DC bias voltage source V_{B}, which is connected to the source terminal of the tenth transistor M₁₀, contributing to the stability of the inverse circuit 302.

Each of these elements works together to ensure that the time delay di is proportional to the input current Iᵢₙ, offering a linear response suitable for a wide range of applications.

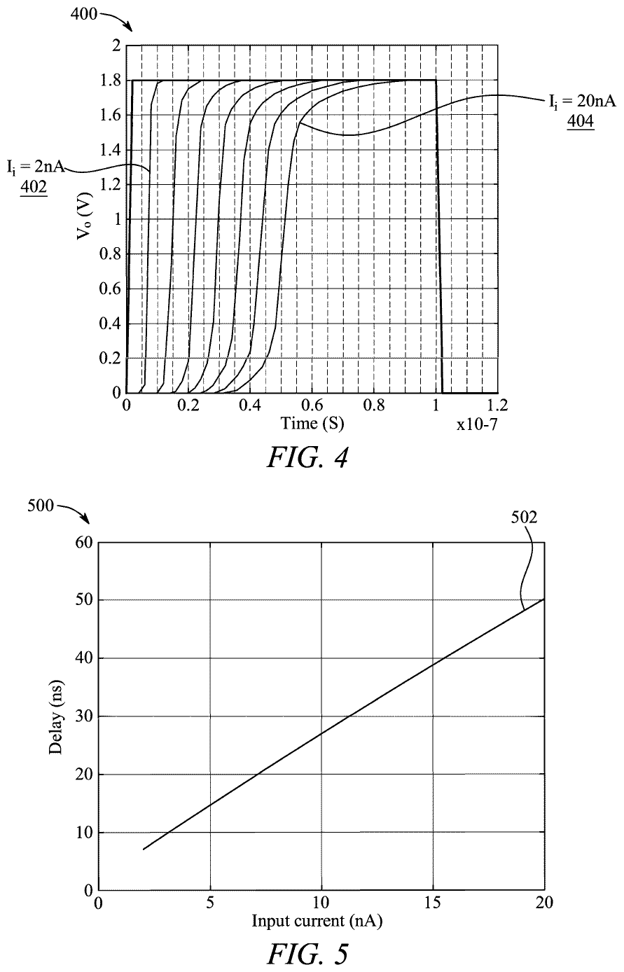

FIG. 4 is a graphical representation of a transient response of the linear CMOS current-to-time converter, implemented using 0.18 μm components sourced from TSMC CMOS technology. TSMC CMOS technology refers to a manufacturing process technology used by Taiwan Semiconductor Manufacturing Company (TSMC) located at TSMC Washington, LLC., Camas, Washington, United States of America. The circuit was simulated using Tanner simulation (Tanner simulation refers to the use of Tanner Designer Tools, a software suite for the design, simulation, and verification of analog, mixed-signal, and MEMS (Microelectromechanical Systems) circuits by Tanner EDA. Tanner Tools is commonly used in the field of electronics and semiconductor design. Tanner EDA is a company based in Monrovia, California, United States of America).

Inverters in the circuit of the converter were supplied with power, 1.8 VDC supply voltage and the clock pulse was composed of a 1.8V peak and 5 MHz frequency. As shown in a graph 400, the input current Iᵢₙ was varied between 2 nA and 20 nA. The response of the output voltage Vₒ for the input current Iᵢₙ=2 nA is shown by curve 402. The response of the output voltage Vₒ for the input current Iᵢₙ=20 nA is shown by curve 404. As evident from the curves of the graph 400, the delay in the output voltage Vₒ increases linearly with the input current, demonstrating the linear relationship between the input current and the time delay dₜ of the output voltage. The delays at V_{DD}/2 are consistently linear across the entire input current range, as shown in FIG. 4.

FIG. 5 presents a graph 500 of the delay di as a function of the input current Iᵢₙ. In the graph 500, curve 502 represents that the delay di varies linearly with the input current Iᵢₙ. The linear relationship indicates the accuracy and consistency of the converter in applications requiring precise time delay generation based on varying input current levels.

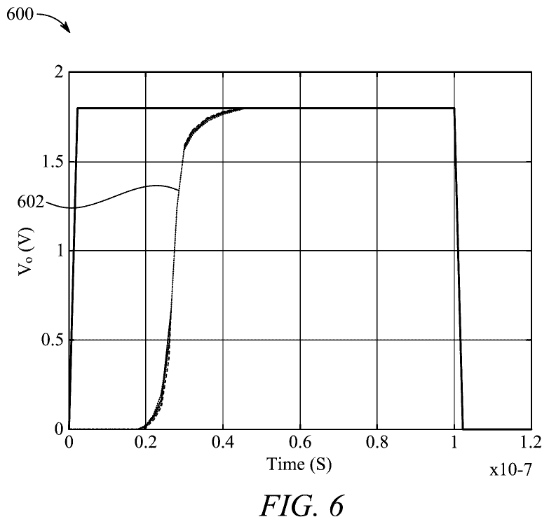

FIG. 6 illustrates a graph 600 representing a temperature analysis conducted with a fixed input current Iᵢₙ of 10 nA, while the temperature was varied in steps of 25° C., ranging from −20° C. to 70° C. Curve 602 represents a response of the converter at different temperatures showing that the circuit response is not affected by temperature variations within the range of −20° C. to 70° C.

In a non-limiting example, the clock generator is an 8284 A clock generator distributed by Jameco Electronics, Belmont, California, United States of America. The frequency of the clock is about 5 MHz.

In a first exemplary embodiment, a linear CMOS current to time converter 300 is described. The linear CMOS current-to-time converter 300 includes a printed circuit board having a positive rail connected to a DC voltage source (V_{DD}) a ground rail connected to a ground and an inverse circuit 302 connected between the positive rail and the ground rail. The inverse circuit 302 is configured to generate an output current Iₒ. The linear CMOS current-to-time converter 300 further includes a mirror transistor M₁₄ connected to the inverse circuit 302. A drain terminal and a gate terminal of the mirror transistor M₁₄ are connected to receive the output current Iₒ and a source terminal of the mirror transistor M₁₄ is connected to the ground rail.

The linear CMOS current-to-time converter 300 further includes the VTC 304 connected between the positive rail of the V_{DD} and the ground rail. The VTC 304 includes a series connection of a first transistor M₁, a second transistor M₂, and a third transistor M₃. A gate terminal of the third transistor M₃ is connected to a gate terminal of the mirror transistor M₁₄ and a source terminal of the third transistor M₃ is connected to the ground rail.

The linear CMOS current-to-time converter 300 further includes a clock generator 306 connected to a gate terminal of the first transistor M₁ and to a gate terminal of the second transistor M₂ and an inverting output digital inverter 308 connected between a drain terminal of the first transistor M₁ and a drain terminal of the second transistor M₂. The digital inverter 308 is configured to generate an output voltage Vₒ. A time delay dₜ of the output voltage Vₒ is linearly proportional to an input current Iᵢₙ.

In one aspect, the series connection of the first transistor M₁, the second transistor M₂, and the third transistor M₃ include a source terminal of the first transistor M₁ connected to the positive rail of the V_{DD}, a drain terminal of the first transistor M₁ connected to a drain terminal of the second transistor M₂, and a source terminal of the second transistor M₂ connected to a drain terminal of the third transistor M₃.

In one aspect, the inverse circuit 302 further includes a fourth transistor M₄, a fifth transistor M₅, a sixth transistor M₆, a seventh transistor M₇, an eighth transistor M₈, a ninth transistor M₉, a tenth transistor M₁₀, an eleventh transistor M₁₁, a twelfth transistor M₁₂ and a thirteenth transistor M₁₃, wherein the fourth transistor M₄, the fifth transistor M₅, the sixth transistor M₆, the seventh transistor M₇, the eighth transistor M₈, the ninth transistor M₉, the tenth transistor M₁₀, the eleventh transistor M₁₁, the twelfth transistor M₁₂ and the thirteenth transistor M₁₃ each have a gate terminal, a drain terminal and an input terminal.

In one aspect, the first transistor M₁, the fourth transistor M₄, the fifth transistor M₅, the sixth transistor M₆, the seventh transistor M₇, the eighth transistor M₈, the ninth transistor M₉, and the tenth transistor M₁₀ are PMOS transistors, and the second transistor M₂, the third transistor M₃, the eleventh transistor M₁₁, the twelfth transistor M₁₂, the thirteenth transistor M₁₃ and the mirror transistor M₁₄ are NMOS transistors.

In one aspect, the linear CMOS current-to-time converter 300 further includes a source of the input current Iᵢₙ connected between the drain terminal of the ninth transistor M₉ and the ground rail. The source terminal of the ninth transistor M₉ is connected to the positive rail of the V_{DD} and the gate terminal of the ninth transistor M₉ is connected to the drain terminal of the ninth transistor M₉. The linear CMOS current-to-time converter 300 further includes a first fixed current source Iₓ connected between the positive rail of the V_{DD} and the drain terminal of the eleventh transistor M₁₁, and a second fixed current source I_{y} connected between the drain terminal of the fourth transistor M₄ and ground rail. The output current Iₒ is given by:

$${I}_{o} = ( {I}_{x} \times {I}_{y} ) / {I}_{i n} .$$

In one aspect, the linear CMOS current-to-time converter 300 further includes a capacitor C_{L} connected between an input terminal of the digital inverter 308 and the ground. In a non-limiting example, the capacitor C_{L} is 15 farads. The capacitor C_{L} is configured to charge when the first transistor M₁ is ON and the third transistor M₃ is OFF and to discharge through the third transistor M₃ when the first transistor M₁ is OFF and the second transistor M₂ and the third transistor M₃ are ON. A discharge current I_{c} received at the drain terminal of the third transistor M₃ is given by:

$${I}_{c} = k ( {I}_{x} \times {I}_{y} ) / {I}_{i n} = k \times {I}_{0} ,$$

where k is a scaling factor given by an aspect ratio of the third transistor M₃ divided by an aspect ratio of the mirror transistor M₁₄.

In one aspect, the aspect ratio of the mirror transistor M₁₄ is configured to generate a voltage at the gate of the third transistor M₃ which is greater than a threshold voltage of the third transistor M₃.

In one aspect, the linear CMOS current-to-time converter 300 further includes the scaling factor k is given by:

$$k = {W}_{3} \times {L}_{14} / {W}_{14} \times {L}_{3} ,$$

where W₃ represents a channel width of the third transistor M₃, L₁₄ represents a channel length of the mirror transistor M₁₄, W₁₄ represents a channel width of the mirror transistor M₁₄ and L₃ represents a channel length of the third transistor M₃.

In one aspect, the time delay is given by:

$${d}_{t} = ( {C}_{L} \times {V}_{DD} / 2 k ) \times ( {I}_{in} / ( {I}_{x} \times {I}_{y} ) .$$

In one aspect, the inverse circuit 302 further includes an electrical connector between the drain terminal of the eleventh transistor M₁₁ and the gate terminal of the thirteenth transistor M₁₃. The source terminal of the eleventh transistor M₁₁ and the source terminal of the thirteenth transistor M₁₃ are each connected to the ground rail. The inverse circuit 302 further includes an electrical connector between the gate terminal of the eleventh transistor M₁₁ and the gate terminal of the twelfth transistor M₁₂. The source of the twelfth transistor M₁₂ is connected to the ground rail.

The inverse circuit 302 further includes DC bias voltage source V_{B}, an electrical connector between the DC bias voltage source V_{B} and the source terminal of the tenth transistor M₁₀, an electrical connector between the drain terminal of the tenth transistor M₁₀ and the drain terminal of the twelfth transistor M₁₂, an electrical connector between the gate terminal of the tenth transistor M₁₀ and the drain terminal of the tenth transistor M₁₀, an electrical connector between the positive rail of the V_{DD} and the source terminal of the ninth transistor M₉, an electrical connector between the gate terminal of the ninth transistor M₉ and the drain of the ninth transistor M₉, an electrical connector between the positive rail of the V_{DD} and the source terminal of the sixth transistor M₆, an electrical connector between the gate terminal of the sixth transistor M₆ and the drain terminal of the ninth transistor M₉, an electrical connector between the drain terminal of the sixth transistor M₆ and the drain terminal of the thirteenth transistor M₁₃, an electrical connector between the source terminal of the seventh transistor M₇ and the source terminal of the tenth transistor M₁₀, an electrical connector between the gate terminal of the seventh transistor M₇ and the drain terminal of the seventh transistor M₇, an electrical connector between the drain terminal of the seventh transistor M₇ and the source terminal of the eighth transistor M₈, an electrical connector between the gate terminal of the eighth transistor M₈ and the drain terminal of the sixth transistor M₆.

The inverse circuit 302 further includes an electrical connector between the gate terminal of the eighth transistor M₈ and the drain terminal of the eighth transistor M₈. The drain terminal eighth transistor M₈ is connected to the ground rail.

The inverse circuit 302 further includes an electrical connector between the positive rail of the V_{DD} and the source terminal of the fifth transistor M₅, a body terminal of the fifth transistor M₅ connected to a body terminal of the sixth transistor M₆, and an electrical connector between the drain terminal of the fifth transistor M₅ and the drain terminal of the mirror transistor M₁₄. The electrical connector between the drain terminal of the fifth transistor M₅ and the drain terminal of the mirror transistor M₁₄ is configured to provide the output current Iₒ to the drain terminal of the mirror transistor M₁₄.

The inverse circuit 302 further includes an electrical connector between the positive rail of the V_{DD} and the source terminal of the fourth transistor M₄, an electrical connector between the gate terminal of the fourth transistor M₄ and the drain terminal of the fourth transistor M₄, an electrical connector between the drain terminal of the fourth transistor M₄ and the gate terminal of the fifth transistor M₅, and an electrical connector between the drain terminal of the fourth transistor M₄ and the second fixed current source I_{y}.

In second exemplary embodiment, a method for generating output voltage Vₒ which is linearly proportional to an input current Iᵢₙ using a linear CMOS current to time converter is described. The method includes connecting an inverse circuit 302 between a positive rail and a ground rail of a printed circuit board having the positive rail connected to a DC voltage source (V_{DD}) and the ground rail connected to a ground terminal, connecting an input current Iᵢₙ source to the inverse circuit 302, connecting a first fixed current source Iₓ to the inverse circuit 302, and connecting a second fixed current source I_{y} to the inverse circuit 302. The method further includes generating, by the inverse circuit 302, an output current Iₒ, where Iₒ is given by Iₒ=(Iₓ×I_{y})/Iᵢₙ, connecting a drain terminal and a gate terminal of a mirror transistor M₁₄ to the inverse circuit 302, receiving, at the drain terminal of mirror transistor M₁₄, the output current Iₒ, and connecting the VTC 304 between the positive rail of the V_{DD} and the ground rail. The VTC 304 includes a series connection of a first transistor M₁, a second transistor M₂, and a third transistor M₃.

The method further includes connecting a gate terminal of the third transistor M₃ to the gate terminal of the mirror transistor M₁₄ and a source terminal of the third transistor M₃ to the ground rail, applying, by a clock generator 306 connected to a gate terminal of the first transistor M₁ and a gate terminal of the second transistor M₂, a time varying clock signal, and generating, by a digital inverter 308 connected between a drain terminal of the first transistor M₁ and a drain terminal of the second transistor M₂, the output voltage Vₒ having a time delay dₜ which is linearly proportional to the input current Iᵢₙ.

In one aspect, the method includes connecting a capacitor C_{L} between an input terminal of the digital inverter 308 and the ground rail. The capacitor C_{L} is configured to charge through the first transistor M₁ when the first transistor M₁ is ON and the third transistor M₃ is OFF and to discharge through the third transistor M₃ when the first transistor M₁ is OFF and second transistor M₂ and the third transistor M₃ are ON. The method further includes receiving, when the capacitor discharges, a discharge current I_{c} at the drain terminal of the third transistor M₃; wherein the discharge current I_{c} is given by:

$${I}_{c} = k ( {I}_{x} \times {I}_{y} ) / {I}_{in} = k \times {I}_{0} ,$$

where k is a scaling factor given by an aspect ratio of the third transistor M₃ divided by an aspect ratio of the mirror transistor M₁₄.

In one aspect, the method includes configuring a voltage at the gate of the third transistor M₃ to be greater than a threshold voltage of the third transistor M₃ by selecting the aspect ratio W₃/L₃ of the third transistor M₃ and the aspect ratio W₁₄/L₁₄ of the mirror transistor M₁₄ so that the scaling factor k is given by:

$$k = {W}_{3} \times {L}_{14} / {W}_{14} \times {L}_{3} ,$$

where W₃ represents a channel width of the third transistor M₃, L₁₄ represents a channel length of the mirror transistor M₁₄, W₁₄ represents a channel width of the mirror transistor M₁₄ and L₃ represents a channel length of the third transistor M₃.

In an aspect, the method includes calculating the time delay by:

$${d}_{t} = ( {C}_{L} \times {V}_{DD} / 2 k ) \times ( {I}_{in} / ( {I}_{x} \times {I}_{y} ) .$$

In one aspect, the method includes selecting a plurality of transistors of the inverse circuit 302, the plurality of transistors including a fourth transistor M₄, a fifth transistor M₅, a sixth transistor M₆, a seventh transistor M₇, an eighth transistor M₈, a ninth transistor M₉, a tenth transistor M₁₀, an eleventh transistor M₁₁, a twelfth transistor M₁₂ and a thirteenth transistor M₁₃, wherein each of the fourth transistor M₄, the fifth transistor M₅, the sixth transistor M₆, the seventh transistor M₇, the eighth transistor M₈, the ninth transistor M₉, the tenth transistor M₁₀, the eleventh transistor M₁₁, the twelfth transistor M₁₂ and the thirteenth transistor M₁₃ have a gate terminal, a drain terminal and an input terminal.

In one aspect, the method includes selecting the first transistor M₁, the fourth transistor M₄, the fifth transistor M₅, the sixth transistor M₆, the seventh transistor M₇, the eighth transistor M₈, the ninth transistor M₉, and the tenth transistor M₁₀ to be PMOS transistors and the second transistor M₂, the third transistor M₃, the eleventh transistor M₁₁, the twelfth transistor M₁₂, the thirteenth transistor M₁₃ and the mirror transistor M₁₄ to be NMOS transistors.

In one aspect, the method includes connecting the VTC 304 between the positive rail of the V_{DD} and the ground rail, by connecting a source terminal of the first transistor M₁ to the positive rail of the V_{DD}, connecting a drain terminal of the first transistor M₁ to a drain terminal of the second transistor M₂, connecting a source terminal of the second transistor M₂ to a drain terminal of the third transistor M₃, and connecting a drain terminal of the third transistor M₃ to the ground rail.

In one aspect, connecting the inverse circuit 302 between a positive rail of the V_{DD} and the ground rail further includes connecting an electrical connector between the drain terminal of the eleventh transistor M₁₁ and the gate terminal of the thirteenth transistor M₁₃, where the source terminal of the eleventh transistor M₁₁ and the source terminal of the thirteenth transistor M₁₃ are each connected to the ground rail, connecting an electrical connector between the gate terminal of the eleventh transistor M₁₁ and the gate terminal of the twelfth transistor M₁₂, where the source of the twelfth transistor M₁₂ is connected to the ground rail, connecting a DC bias voltage source V_{B} by an electrical connector to the source terminal of the tenth transistor M₁₀, and connecting an electrical connector between the drain terminal of the tenth transistor M₁₀ and the drain terminal of the twelfth transistor M₁₂.

The connecting the inverse circuit 302 between a positive rail of the V_{DD} and the ground rail further includes connecting an electrical connector between the gate terminal of the tenth transistor M₁₀ and the drain terminal of the tenth transistor M₁₀, connecting an electrical connector between the positive rail of the V_{DD} and the source terminal of the ninth transistor M₉, connecting an electrical connector between the gate terminal of the ninth transistor M₉ and the drain of the ninth transistor M₉, connecting an electrical connector between the positive rail of the V_{DD} and the source terminal of the sixth transistor M₆, connecting an electrical connector between the gate terminal of the sixth transistor M₆ and the drain terminal of the ninth transistor M₉, connecting an electrical connector between the drain terminal of the sixth transistor M₆ and the drain terminal of the thirteenth transistor M₁₃, connecting an electrical connector between the source terminal of the seventh transistor M₇ and the source terminal of the tenth transistor M₁₀, connecting an electrical connector between the gate terminal of the seventh transistor M₇ and the drain terminal of the seventh transistor M₇, connecting an electrical connector between the drain terminal of the seventh transistor M₇ and the source terminal of the eighth transistor M₈;

The connecting the inverse circuit 302 between a positive rail of the V_{DD} and the ground rail further includes connecting an electrical connector between the gate terminal of the eighth transistor M₈ and the drain terminal of the sixth transistor M₆, connecting an electrical connector between the gate terminal of the eighth transistor M₈ and the drain terminal of the eighth transistor M₈, wherein the drain terminal eighth transistor M₈ is connected to the ground rail, connecting an electrical connector between the positive rail of the V_{DD} and the source terminal of the fifth transistor M₅, connecting an electrical connector between a body terminal of the fifth transistor M₅ and a body terminal of the sixth transistor M₆, connecting an electrical connector between the drain terminal of the fifth transistor M₅ and the drain terminal of the mirror transistor M₁₄, where the electrical connector between the drain terminal of the fifth transistor M₅ and the drain terminal of the mirror transistor M₁₄ is configured to provide the output current I₀ to the drain terminal of the mirror transistor M₁₄.

The connecting the inverse circuit 302 between a positive rail of the V_{DD} and the ground rail further includes connecting an electrical connector between the positive rail of the V_{DD} and the source terminal of the fourth transistor M₄, connecting an electrical connector between the gate terminal of the fourth transistor M₄ and the drain terminal of the fourth transistor M₄, connecting an electrical connector between the drain terminal of the fourth transistor M₄ and the gate terminal of the fifth transistor M₅, and connecting an electrical connector between the drain terminal of the fourth transistor M₄ and the second fixed current source I_{y}.

In one aspect, the method further includes selecting a voltage of the DC voltage source V_{DD} from a range comprising about 1.5 V to about 2.5 V, selecting a voltage of the clock generator 306 from a range comprising about 1.3 V peak voltage to about 2.3 V peak voltage, selecting a frequency of the clock generator 306 to be about 5 MHz respectively, selecting the input current Iᵢₙ from a range comprising about 2 nA to about 20 nA, selecting the first fixed current source Iₓ to be about 20 nA, selecting the second fixed current source Iₓ to be about 20 nA, and selecting the bias voltage V_{B} to be about 0.9 V.

In third exemplary embodiment, a method of converting an input current Iᵢₙ to an output voltage Vₒ having a time delay dₜ proportional to the input current Iᵢₙ is described. The method includes connecting an inverse circuit 302 of a linear CMOS current to time converter having a first plurality of CMOS transistors to a positive voltage rail connected to a DC voltage source (V_{DD}), connecting a ground rail of the inverse circuit 302 to a ground terminal, connecting a drain terminal and a gate terminal of a mirror transistor M₁₄ to the inverse circuit 302, connecting a drain terminal and a gate terminal of a mirror transistor M₁₄ to the inverse circuit 302, and connecting the VTC 304 between the positive rail of the V_{DD} and the ground rail. The VTC 304 includes a series connection of a second plurality of CMOS transistors comprising first transistor M₁, a second transistor M₂ and a third transistor M₃. The first transistor M₁ is a PMOS transistor and the second transistor M₂ and the third transistor M₃ are NMOS transistors. In a non-limiting example, the aspect ratios of M₁ through M₁₃ are each 2.0/0.18.

The method further includes connecting a gate terminal of the third transistor M₃ to the gate terminal of the mirror transistor M₁₄ and connecting a source terminal of the third transistor M₃ to the ground rail, connecting a digital inverter 308 between a drain terminal of the first transistor M₁ and a drain terminal of the second transistor M₂, configuring a voltage at the gate of the third transistor M₃ to be greater than a threshold voltage of the third transistor M₃ by selecting an aspect ratio W₃/L₃ of the third transistor M₃ and the aspect ratio W₁₄/L₁₄ of the mirror transistor M₁₄ so that a scaling factor k is given by:

$$k = {W}_{3} \times {L}_{14} / {W}_{14} \times {L}_{3} ,$$

where W₃ represents a channel width of the third transistor M₃, L₁₄ represents a channel length of the mirror transistor M₁₄, W₁₄ represents a channel width of the mirror transistor M₁₄, and L₃ represents a channel length of the third transistor M₃.

The method further includes connecting a capacitor C_{L} between an input terminal of the digital inverter 308 and the ground rail, applying the input current Iᵢₙ, a first fixed current Iₓ, a second fixed current I_{y} and a bias voltage V_{B} to the inverse circuit 302 and generating an output current I₀, receiving, at the drain of the mirror transistor, the output current I₀, applying, by a clock generator 306 connected to a gate terminal of the first transistor M₁ and a gate terminal of the second transistor M₂, a time varying clock signal, charging the capacitor C_{L} through the first transistor M₁ when the first transistor M₁ is ON and the third transistor M₃ is OFF, discharging the capacitor C_{L} through the third transistor M₃ when the first transistor M₁ is OFF and second transistor M₂ and the third transistor M₃ are ON, and generating, by the digital inverter 308, the output voltage Vₒ, having a time delay de which is linearly proportional to the input current Iᵢₙ, wherein the time delay dₜ is given by:

$${d}_{t} = ( {C}_{L} \times {V}_{DD} / 2 k ) \times ( {I}_{in} / ( {I}_{x} \times {I}_{y} ) .$$

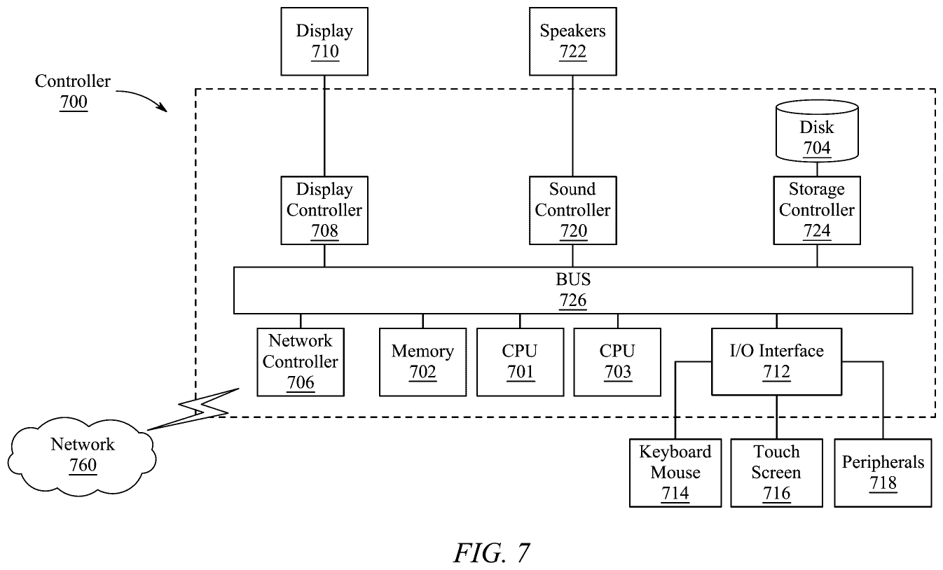

Next, further details of the hardware description of the computing environment according to exemplary embodiments is described with reference to FIG. 7. In FIG. 7, a controller 700 is described is representative of the clock circuit 306 of system 300 of FIG. 3 in which the controller is a computing device which includes a CPU 701 which performs the processes described above/below. The process data and instructions may be stored in memory 702. These processes and instructions may also be stored on a storage medium disk 704 such as a hard drive (HDD) or portable storage medium or may be stored remotely.

Further, the claims are not limited by the form of the computer-readable media on which the instructions of the inventive process are stored. For example, the instructions may be stored on CDs, DVDs, in FLASH memory, RAM, ROM, PROM, EPROM, EEPROM, hard disk or any other information processing device with which the computing device communicates, such as a server or computer.

Further, the claims may be provided as a utility application, background daemon, or component of an operating system, or combination thereof, executing in conjunction with CPU 701, 703 and an operating system such as Microsoft Windows 7, Microsoft Windows 10, Microsoft Windows 11, UNIX, Solaris, LINUX, Apple MAC-OS and other systems known to those skilled in the art.

The hardware elements in order to achieve the computing device may be realized by various circuitry elements, known to those skilled in the art. For example, CPU 701 or CPU 703 may be a Xenon or Core processor from Intel of America or an Opteron processor from AMD of America, or may be other processor types that would be recognized by one of ordinary skill in the art. Alternatively, the CPU 701, 703 may be implemented on an FPGA, ASIC, PLD or using discrete logic circuits, as one of ordinary skill in the art would recognize. Further, CPU 701, 703 may be implemented as multiple processors cooperatively working in parallel to perform the instructions of the inventive processes described above.

The computing device in FIG. 7 also includes a network controller 706, such as an Intel Ethernet PRO network interface card from Intel Corporation of America, for interfacing with network 760. As can be appreciated, the network 760 can be a public network, such as the Internet, or a private network such as an LAN or WAN network, or any combination thereof and can also include PSTN or ISDN sub-networks. The network 760 can also be wired, such as an Ethernet network, or can be wireless such as a cellular network including EDGE, 3G, 4G, 5G and 6G wireless cellular systems. The wireless network can also be Wi-Fi, Bluetooth, or any other wireless form of communication that is known.

The computing device further includes a display controller 708, such as a NVIDIA GeForce GTX or Quadro graphics adaptor from NVIDIA Corporation of America for interfacing with display 710, such as a Hewlett Packard HPL2445w LCD monitor. A general purpose I/O interface 712 interfaces with a keyboard and/or mouse 714 as well as a touch screen panel 716 on or separate from display 710. General purpose I/O interface also connects to a variety of peripherals 718 including printers and scanners, such as an OfficeJet or DeskJet from Hewlett Packard.

A sound controller 720 is also provided in the computing device such as Sound Blaster X-Fi Titanium from Creative, to interface with speakers/microphone 722 thereby providing sounds and/or music.

The general purpose storage controller 724 connects the storage medium disk 704 with communication bus 726, which may be an ISA, EISA, VESA, PCI, or similar, for interconnecting all of the components of the computing device. A description of the general features and functionality of the display 710, keyboard and/or mouse 714, as well as the display controller 708, storage controller 724, network controller 706, sound controller 720, and general purpose I/O interface 712 is omitted herein for brevity as these features are known.

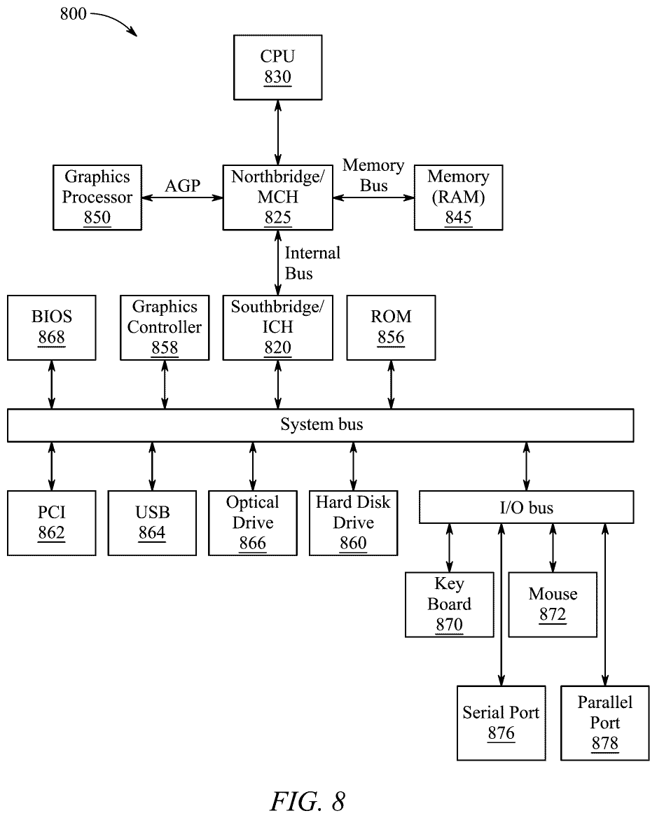

The exemplary circuit elements described in the context of the present disclosure may be replaced with other elements and structured differently than the examples provided herein. Moreover, circuitry configured to perform features described herein may be implemented in multiple circuit units (e.g., chips), or the features may be combined in circuitry on a single chipset, as shown on FIG. 8.

FIG. 8 shows a schematic diagram of a data processing system, according to certain embodiments, for performing the functions of the exemplary embodiments. The data processing system is an example of a computer in which code or instructions implementing the processes of the illustrative embodiments may be located.

In FIG. 8, data processing system 800 employs a hub architecture including a north bridge and memory controller hub (NB/MCH) 825 and a south bridge and input/output (I/O) controller hub (SB/ICH) 820. The central processing unit (CPU) 830 is connected to NB/MCH 825. The NB/MCH 825 also connects to the memory 845 via a memory bus, and connects to the graphics processor 850 via an accelerated graphics port (AGP). The NB/MCH 825 also connects to the SB/ICH 820 via an internal bus (e.g., a unified media interface or a direct media interface). The CPU Processing unit 830 may contain one or more processors and even may be implemented using one or more heterogeneous processor systems.

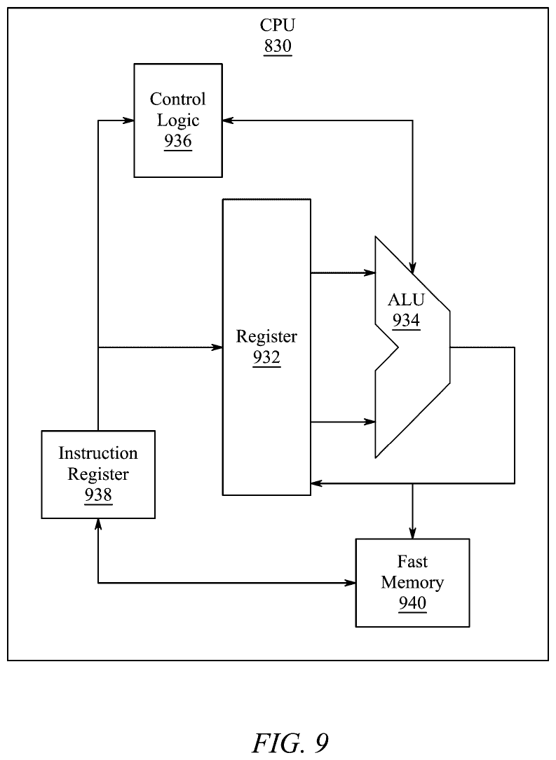

For example, FIG. 9 shows one implementation of CPU 830. In one implementation, the instruction register 938 retrieves instructions from the fast memory 940. At least part of these instructions are fetched from the instruction register 938 by the control logic 936 and interpreted according to the instruction set architecture of the CPU 830. Part of the instructions can also be directed to the register 932. In one implementation the instructions are decoded according to a hardwired method, and in another implementation the instructions are decoded according a microprogram that translates instructions into sets of CPU configuration signals that are applied sequentially over multiple clock pulses. After fetching and decoding the instructions, the instructions are executed using the arithmetic logic unit (ALU) 934 that loads values from the register 932 and performs logical and mathematical operations on the loaded values according to the instructions. The results from these operations can be feedback into the register and/or stored in the fast memory 940. According to certain implementations, the instruction set architecture of the CPU 830 can use a reduced instruction set architecture, a complex instruction set architecture, a vector processor architecture, a very large instruction word architecture.

Furthermore, the CPU 830 can be based on the Von Neuman model or the Harvard model. The CPU 830 can be a digital signal processor, an FPGA, an ASIC, a PLA, a PLD, or a CPLD. Further, the CPU 830 can be an x86 processor by Intel or by AMD; an ARM processor, a Power architecture processor by, e.g., IBM; a SPARC architecture processor by Sun Microsystems or by Oracle; or other known CPU architecture.

Referring again to FIG. 8, the data processing system 800 can include that the SB/ICH 820 is coupled through a system bus to an I/O Bus, a read only memory (ROM) 856, universal serial bus (USB) port 864, a flash binary input/output system (BIOS) 868, and a graphics controller 858. PCI/PCIe devices can also be coupled to SB/ICH 888 through a PCI bus 862.

The PCI devices may include, for example, Ethernet adapters, add-in cards, and PC cards for notebook computers. The Hard disk drive 860 and CD-ROM 866 can use, for example, an integrated drive electronics (IDE) or serial advanced technology attachment (SATA) interface. In one implementation, the I/O bus can include a super I/O (SIO) device.

Further, the hard disk drive (HDD) 860 and optical drive 866 can also be coupled to the SB/ICH 820 through a system bus. In one implementation, a keyboard 870, a mouse 872, a parallel port 878, and a serial port 876 can be connected to the system bus through the I/O bus. Other peripherals and devices that can be connected to the SB/ICH 820 using a mass storage controller such as SATA or PATA, an Ethernet port, an ISA bus, a LPC bridge, SMBus, a DMA controller, and an Audio Codec.

Moreover, the present disclosure is not limited to the specific circuit elements described herein, nor is the present disclosure limited to the specific sizing and classification of these elements. For example, the skilled artisan will appreciate that the circuitry described herein may be adapted based on changes on battery sizing and chemistry or based on the requirements of the intended back-up load to be powered.

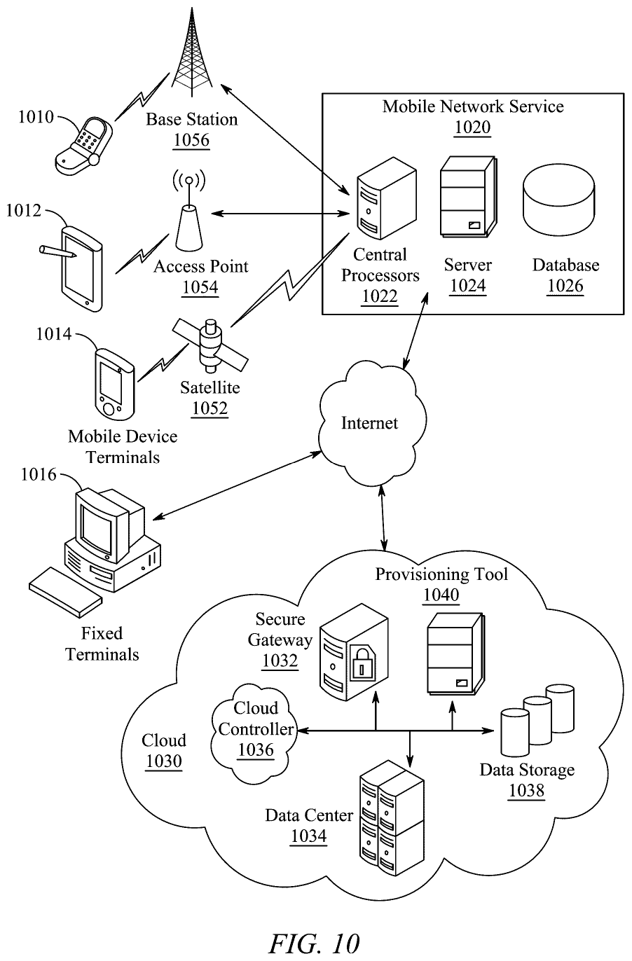

The functions and features described herein may also be executed by various distributed components of a system. For example, one or more processors may execute these system functions, wherein the processors are distributed across multiple components communicating in a network. The distributed components may include one or more client and server machines, such as cloud 1030 including a cloud controller 1036, a secure gateway 1032, a data center 1034, data storage 1038 and a provisioning tool 1040, and mobile network services 1020 including central processors 1022, a server 1024 and a database 1026, which may share processing, as shown by FIG. 10, in addition to various human interface and communication devices (e.g., display monitors 1016, smart phones 1010, tablets 1012, personal digital assistants (PDAs) 1014). The network may be a private network, such as a LAN, satellite 1052 or WAN 1054, or be a public network, may such as the Internet. Input to the system may be received via direct user input and received remotely either in real-time or as a batch process. Additionally, some implementations may be performed on modules or hardware not identical to those described. Accordingly, other implementations are within the scope that may be claimed.

The above-described hardware description is a non-limiting example of corresponding structure for performing the functionality described herein.

Numerous modifications and variations of the present disclosure are possible in light of the above teachings. It is therefore to be understood that within the scope of the appended claims, the invention may be practiced otherwise than as specifically described herein.

1. A linear CMOS current to time converter, comprising:
a printed circuit board having a positive rail connected to a DC voltage source (V_{DD}) and a ground rail connected to a ground;
an inverse circuit connected between the positive rail of and the ground rail, wherein the inverse circuit is configured to generate an output current Iₒ;
a mirror transistor M₁₄ connected to the inverse circuit, wherein a drain terminal and a gate terminal of the mirror transistor M₁₄ are connected to receive the output current Iₒ and a source terminal of the mirror transistor M₁₄ is connected to the ground rail;
a voltage to time converter (VTC) connected between the positive rail of the V_{DD} and the ground rail, wherein the VTC includes a series connection of a first transistor M₁, a second transistor M₂ and a third transistor M₃, wherein a gate terminal of the third transistor M₃ is connected to a gate terminal of the mirror transistor M₁₄ and a source terminal of the third transistor M₃ is connected to the ground rail;
a clock generator connected to a gate terminal of the first transistor M₁ and to a gate terminal of the second transistor M₂; and
a digital inverter connected between a drain terminal of the first transistor M₁ and a drain terminal of the second transistor M₂, wherein the digital inverter is configured to generate an output voltage Vₒ,
wherein a time delay dₜ of the output voltage Vₒ is linearly proportional to an input current Iᵢₙ.

2. The linear CMOS current to time converter of claim 1, wherein the series connection of the first transistor M₁, the second transistor M₂ and the third transistor M₃ comprises:
a source terminal of the first transistor M₁ connected to the positive rail of the V_{DD};
a drain terminal of the first transistor M₁ connected to a drain terminal of the second transistor M₂; and
a source terminal of the second transistor M₂ connected to a drain terminal of the third transistor M₃.

3. The linear CMOS current to time converter of claim 2, wherein the inverse circuit further comprises:
a fourth transistor M₄, a fifth transistor M₅, a sixth transistor M₆, a seventh transistor M₇, an eighth transistor M₈, a ninth transistor M₉, a tenth transistor M₁₀, an eleventh transistor M₁₁, a twelfth transistor M₁₂ and a thirteenth transistor M₁₃, wherein the fourth transistor M₄, the fifth transistor M₅, the sixth transistor M₆, the seventh transistor M₇, the eighth transistor M₈, the ninth transistor M₉, the tenth transistor M₁₀, the eleventh transistor M₁₁, the twelfth transistor M₁₂ and the thirteenth transistor M₁₃ each have a gate terminal, a drain terminal and an input terminal.

4. The linear CMOS current to time converter of claim 3, wherein the first transistor M₁, the fourth transistor M₄, the fifth transistor M₅, the sixth transistor M₆, the seventh transistor M₇, the eighth transistor M₈, the ninth transistor M₉ and the tenth transistor M₁₀ are PMOS transistors and the second transistor M₂, the third transistor M₃, the eleventh transistor M₁₁, the twelfth transistor M₁₂, the thirteenth transistor M₁₃ and the mirror transistor M₁₄ are NMOS transistors.

5. The linear CMOS current to time converter of claim 4, further comprising:
a source of the input current Iᵢₙ connected between the drain terminal of the ninth transistor M₉ and the ground rail, wherein the source terminal of the ninth transistor M₉ is connected to the positive rail of the V_{DD} and the gate terminal of the ninth transistor M₉ is connected to the drain terminal of the ninth transistor M₉;
a first fixed current source Iₓ connected between the positive rail of the V_{DD} and the drain terminal of the eleventh transistor M₁₁;
a second fixed current source I_{y} connected between the drain terminal of the fourth transistor M₄ and ground rail, wherein the output current Iₒ is given by:
$${I}_{o} = ( {I}_{x} \times {I}_{y} ) / {I}_{in} .$$

6. The linear CMOS current to time converter of claim 5, further comprising:
a capacitor C_{L} connected between an input terminal of the digital inverter and the ground, wherein the capacitor C_{L} is configured to charge when the first transistor M₁ is ON and the third transistor M₃ is OFF and to discharge through the third transistor M₃ when the first transistor M₁ is OFF and second transistor M₂ and the third transistor M₃ are ON, wherein a discharge current I_{c} received at the drain terminal of the third transistor M₃ is given by:
$${I}_{c} = k ( {I}_{x} \times {I}_{y} ) / {I}_{in} = k \times {I}_{0} ,$$
where k is a scaling factor given by an aspect ratio of the third transistor M₃ divided by an aspect ratio of the mirror transistor M₁₄.

7. The linear CMOS current to time converter of claim 6, wherein the aspect ratio of the mirror transistor M₁₄ is configured to generate a voltage at the gate of the third transistor M₃ which is greater than a threshold voltage of the third transistor M₃.

8. The linear CMOS current to time converter of claim 6, wherein the scaling factor k is given by:
$$k = {W}_{3} \times {L}_{14} / {W}_{14} \times {L}_{3} ,$$
where W₃ represents a channel width of the third transistor M₃, L₁₄ represents a channel length of the mirror transistor M₁₄, W₁₄ represents a channel width of the mirror transistor M₁₄ and L₃ represents a channel length of the third transistor M₃.

9. The linear CMOS current to time converter of claim 8, wherein the time delay is given by:
$${d}_{t} = ( {C}_{L} \times {V}_{DD} / 2 k ) \times ( {I}_{in} / ( {I}_{x} \times {I}_{y} ) .$$

10. The linear CMOS current to time converter of claim 6, wherein the inverse circuit further comprises:
an electrical connector between the drain terminal of the eleventh transistor Mu and the gate terminal of the thirteenth transistor M₁₃, wherein the source terminal of the eleventh transistor M₁₁ and the source terminal of the thirteenth transistor M₁₃ are each connected to the ground rail;
an electrical connector between the gate terminal of the eleventh transistor M₁₁ and the gate terminal of the twelfth transistor M₁₂, wherein the source of the twelfth transistor M₁₂ is connected to the ground rail;
a DC bias voltage source V_{B};
an electrical connector between the DC bias voltage source V_{B} and the source terminal of the tenth transistor M₁₀;
an electrical connector between the drain terminal of the tenth transistor M₁₀ and the drain terminal of the twelfth transistor M₁₂;
an electrical connector between the gate terminal of the tenth transistor M₁₀ and the drain terminal of the tenth transistor M₁₀;
an electrical connector between the positive rail of the V_{DD} and the source terminal of the ninth transistor M₉;
an electrical connector between the gate terminal of the ninth transistor M₉ and the drain of the ninth transistor M₉;
an electrical connector between the positive rail of the V_{DD} and the source terminal of the sixth transistor M₆;
an electrical connector between the gate terminal of the sixth transistor M₆ and the drain terminal of the ninth transistor M₉;
an electrical connector between the drain terminal of the sixth transistor M₆ and the drain terminal of the thirteenth transistor M₁₃;
an electrical connector between the source terminal of the seventh transistor M₇ and the source terminal of the tenth transistor M₁₀;
an electrical connector between the gate terminal of the seventh transistor M₇ and the drain terminal of the seventh transistor M₇;
an electrical connector between the drain terminal of the seventh transistor M₇ and the source terminal of the eighth transistor M₈;
an electrical connector between the gate terminal of the eighth transistor M₈ and the drain terminal of the sixth transistor M₆;
an electrical connector between the gate terminal of the eighth transistor M₅ and the drain terminal of the eighth transistor M₈, wherein the drain terminal eighth transistor M₈ is connected to the ground rail;
an electrical connector between the positive rail of the V_{DD} and the source terminal of the fifth transistor M₅;
a body terminal of the fifth transistor M₅ connected to a body terminal of the sixth transistor M₆;
an electrical connector between the drain terminal of the fifth transistor M₅ and the drain terminal of the mirror transistor M₁₄, wherein the electrical connector between the drain terminal of the fifth transistor M₅ and the drain terminal of the mirror transistor M₁₄ is configured to provide the output current Iₒ to the drain terminal of the mirror transistor M₁₄;
an electrical connector between the positive rail of the V_{DD} and the source terminal of the fourth transistor M₄;
an electrical connector between the gate terminal of the fourth transistor M₄ and the drain terminal of the fourth transistor M₄;
an electrical connector between the drain terminal of the fourth transistor M₄ and the gate terminal of the fifth transistor M₅; and
an electrical connector between the drain terminal of the fourth transistor M₄ and the second fixed current source I_{y}.

11. A method for generating an output voltage Vₒ which is linearly proportional to an input current Iᵢₙ using a linear CMOS current to time converter, comprising:
connecting an inverse circuit between a positive rail of and a ground rail of a printed circuit board having the positive rail connected to a DC voltage source (V_{DD}) and the ground rail connected to a ground terminal;
connecting an input current Iᵢₙ source to the inverse circuit;
connecting a first fixed current source Iₓ to the inverse circuit;
connecting a second fixed current source I_{y} to the inverse circuit;
generating, by the inverse circuit, an output current Iₒ, where Iₒ is given by Iₒ=(Iₓ×I_{y})/Iᵢₙ;
connecting a drain terminal and a gate terminal of a mirror transistor M₁₄ to the inverse circuit;
receiving, at the drain terminal of mirror transistor M₁₄, the output current Iₒ;
connecting a voltage to time converter (VTC) between the positive rail of the V_{DD} and the ground rail, wherein the VTC includes a series connection of a first transistor M₁, a second transistor M₂ and a third transistor M₃;
connecting a gate terminal of the third transistor M₃ to the gate terminal of the mirror transistor M₁₄ and a source terminal of the third transistor M₃ to the ground rail;
applying, by a clock generator connected to a gate terminal of the first transistor M₁ and a gate terminal of the second transistor M₂, a time varying clock signal; and
generating, by a digital inverter connected between a drain terminal of the first transistor M₁ and a drain terminal of the second transistor M₂, the output voltage Vₒ having a time delay dₜ which is linearly proportional to the input current Iᵢₙ.

12. The method of claim 11, further comprising:
connecting a capacitor C_{L} between an input terminal of the digital inverter and the ground rail, wherein the capacitor C_{L} is configured to charge through the first transistor M₁ when the first transistor M₁ is ON and the third transistor M₃ is OFF and to discharge through the third transistor M₃ when the first transistor M₁ is OFF and second transistor M₂ and the third transistor M₃ are ON; and
receiving, when the capacitor discharges, a discharge current I_{c} at the drain terminal of the third transistor M₃; wherein the discharge current I_{c} is given by:
$${I}_{c} = k ( {I}_{x} \times {I}_{y} ) / {I}_{in} = k \times {I}_{0} ,$$
where k is a scaling factor given by an aspect ratio of the third transistor M₃ divided by an aspect ratio of the mirror transistor M₁₄.

13. The method of claim 12, further comprising:
configuring a voltage at the gate of the third transistor M₃ to be greater than a threshold voltage of the third transistor M₃ by selecting the aspect ratio W₃/L₃ of the third transistor M₃ and the aspect ratio W₁₄/L₁₄ of the mirror transistor M₁₄ so that the scaling factor k is given by:
$$k = {W}_{3} \times {L}_{14} / {W}_{14} \times {L}_{3} ,$$
where W₃ represents a channel width of the third transistor M₃, L₁₄ represents a channel length of the mirror transistor M₁₄, W₁₄ represents a channel width of the mirror transistor M₁₄ and L₃ represents a channel length of the third transistor M₃.

14. The method of claim 13, further comprising:
calculating the time delay by:
$${d}_{t} = ( {C}_{L} \times {V}_{DD} / 2 k ) \times ( {I}_{in} / ( {I}_{x} \times {I}_{y} ) .$$

15. The method of claim 14, further comprising:
selecting a plurality of transistors of the inverse circuit, the plurality of transistors including a fourth transistor M₄, a fifth transistor M₅, a sixth transistor M₆, a seventh transistor M₇, an eighth transistor M₈, a ninth transistor M₉, a tenth transistor M₁₀, an eleventh transistor M₁₁, a twelfth transistor M₁₂ and a thirteenth transistor M₁₃, wherein each of the fourth transistor M₄, the fifth transistor M₅, the sixth transistor M₆, the seventh transistor M₇, the eighth transistor M₈, the ninth transistor M₉, the tenth transistor M₁₀, the eleventh transistor M₁₁, the twelfth transistor M₁₂ and the thirteenth transistor M₁₃ have a gate terminal, a drain terminal and an input terminal.

16. The method of claim 15, further comprising:
selecting the first transistor M₁, the fourth transistor M₄, the fifth transistor M₅, the sixth transistor M₆, the seventh transistor M₇, the eighth transistor M₈, the ninth transistor M₉ and the tenth transistor M₁₀ to be PMOS transistors and the second transistor M₂, the third transistor M₃, the eleventh transistor M₁₁, the twelfth transistor M₁₂, the thirteenth transistor M₁₃ and the mirror transistor M₁₄ to be NMOS transistors.

17. The method of claim 16, further comprising:
connecting the voltage to time converter (VTC) between the positive rail of the V_{DD} and the ground rail, by:
connecting a source terminal of the of the first transistor M₁ to the positive rail of the V_{DD};
connecting a drain terminal of the first transistor M₁ to a drain terminal of the second transistor M₂;
connecting a source terminal of the second transistor M₂ to a drain terminal of the third transistor M₃; and
connecting a drain terminal of the third transistor M₃ to the ground rail.

18. The method of claim 17, wherein connecting the inverse circuit between a positive rail of the V_{DD} and the ground rail further comprises:
connecting an electrical connector between the drain terminal of the eleventh transistor M₁₁ and the gate terminal of the thirteenth transistor M₁₃, wherein the source terminal of the eleventh transistor M₁₁ and the source terminal of the thirteenth transistor M₁₃ are each connected to the ground rail;
connecting an electrical connector between the gate terminal of the eleventh transistor M₁₁ and the gate terminal of the twelfth transistor M₁₂, wherein the source of the twelfth transistor M₁₂ is connected to the ground rail;
connecting a DC bias voltage source V_{B} by an electrical connector to the source terminal of the tenth transistor M₁₀;
connecting an electrical connector between the drain terminal of the tenth transistor M₁₀ and the drain terminal of the twelfth transistor M₁₂;
connecting an electrical connector between the gate terminal of the tenth transistor M₁₀ and the drain terminal of the tenth transistor M₁₀;
connecting an electrical connector between the positive rail of the V_{DD} and the source terminal of the ninth transistor M₉;
connecting an electrical connector between the gate terminal of the ninth transistor M₉ and the drain of the ninth transistor M₉;
connecting an electrical connector between the positive rail of the V_{DD} and the source terminal of the sixth transistor M₆;
connecting an electrical connector between the gate terminal of the sixth transistor M₆ and the drain terminal of the ninth transistor M₉;
connecting an electrical connector between the drain terminal of the sixth transistor M₆ and the drain terminal of the thirteenth transistor M₁₃;
connecting an electrical connector between the source terminal of the seventh transistor M₇ and the source terminal of the tenth transistor M₁₀;
connecting an electrical connector between the gate terminal of the seventh transistor M₇ and the drain terminal of the seventh transistor M₇;
connecting an electrical connector between the drain terminal of the seventh transistor M₇ and the source terminal of the eighth transistor M₈;
connecting an electrical connector between the gate terminal of the eighth transistor M₈ and the drain terminal of the sixth transistor M₆;
connecting an electrical connector between the gate terminal of the eighth transistor M₈ and the drain terminal of the eighth transistor M₈, wherein the drain terminal eighth transistor M₈ is connected to the ground rail;
connecting an electrical connector between the positive rail of the V_{DD} and the source terminal of the fifth transistor M₅;
connecting an electrical connector between a body terminal of the fifth transistor M₅ and a body terminal of the sixth transistor M₆;
connecting an electrical connector between the drain terminal of the fifth transistor M₅ and the drain terminal of the mirror transistor M₁₄, wherein the electrical connector between the drain terminal of the fifth transistor M₅ and the drain terminal of the mirror transistor M₁₄ is configured to provide the output current I₀ to the drain terminal of the mirror transistor M₁₄;
connecting an electrical connector between the positive rail of the V_{DD} and the source terminal of the fourth transistor M₄;
connecting an electrical connector between the gate terminal of the fourth transistor M₄ and the drain terminal of the fourth transistor M₄;
connecting an electrical connector between the drain terminal of the fourth transistor M₄ and the gate terminal of the fifth transistor M₅; and
connecting an electrical connector between the drain terminal of the fourth transistor M₄ and the second fixed current source I_{y}.

19. The method of claim 18, further comprising:
selecting a voltage of the DC voltage source V_{DD} from a range comprising about 1.5 V to about 2.5 V;
selecting a voltage of the clock generator from a range comprising about 1.3 V peak voltage to about 2.3 V peak voltage;
selecting a frequency of the clock generator to be about 5 MHz respectively;
selecting the input current Iᵢₙ from a range comprising about 2 nA to about 20 nA;
selecting the first fixed current source Iₓ to be about 20 nA;
selecting the second fixed current source Iₓ to be about 20 nA; and
selecting the bias voltage V_{B} to be about 0.9 V.

20. A method of converting an input current Iᵢₙ to an output voltage Vₒ having a time delay de proportional to the input current Iᵢₙ, comprising:
connecting an inverse circuit of a linear CMOS current to time converter having a first plurality of CMOS transistors to a positive voltage rail connected to a DC voltage source (V_{DD});
connecting a ground rail of the inverse circuit to a ground terminal; and
connecting a drain terminal and a gate terminal of a mirror transistor M₁₄ to the inverse circuit;
connecting a drain terminal and a gate terminal of a mirror transistor M₁₄ to the inverse circuit;
connecting a voltage to time converter (VTC) between the positive rail of the V_{DD} and the ground rail, wherein the VTC includes a series connection of a second plurality of CMOS transistors comprising first transistor M₁, a second transistor M₂ and a third transistor M₃, wherein the first transistor M₁ is a PMOS transistor and the second transistor M₂ and the third transistor M₃ are NMOS transistors;
connecting a gate terminal of the third transistor M₃ to the gate terminal of the mirror transistor M₁₄ and connecting a source terminal of the third transistor M₃ to the ground rail;
connecting a digital inverter between a drain terminal of the first transistor M₁ and a drain terminal of the second transistor M₂;
configuring a voltage at the gate of the third transistor M₃ to be greater than a threshold voltage of the third transistor M₃ by selecting an aspect ratio W₃/L₃ of the third transistor M₃ and the aspect ratio W₁₄/L₁₄ of the mirror transistor M₁₄ so that a scaling factor k is given by:
$$k = {W}_{3} \times {L}_{14} / {W}_{14} \times {L}_{3} ,$$
where W₃ represents a channel width of the third transistor M₃, L₁₄ represents a channel length of the mirror transistor M₁₄, W₁₄ represents a channel width of the mirror transistor M₁₄ and L₃ represents a channel length of the third transistor M₃;
connecting a capacitor C_{L} between an input terminal of the digital inverter and the ground rail;
applying the input current Iᵢₙ, a first fixed current Iₓ, a second fixed current I_{y} and a bias voltage V_{B} to the inverse circuit and generating an output current I₀;
receiving, at the drain of the mirror transistor, the output current I₀;
applying, by a clock generator connected to a gate terminal of the first transistor M₁ and a gate terminal of the second transistor M₂, a time varying clock signal;
charging the capacitor C_{L} through the first transistor M₁ when the first transistor M₁ is ON and the third transistor M₃ is OFF;
discharging the capacitor C_{L} through the third transistor M₃ when the first transistor M₁ is OFF and second transistor M₂ and the third transistor M₃ are ON;
generating, by the inverting output amplifier, the output voltage Vₒ, having a time delay dₜ which is linearly proportional to the input current Iᵢₙ, wherein the time delay dₜ is given by:
$${d}_{t} = ( {C}_{L} \times {V}_{DD} / 2 k ) \times ( {I}_{in} / ( {I}_{x} \times {I}_{y} ) .$$
